(19) United States
(12) Patent Application Publication
(10) Pub. No.: US 2014/0036469 A1
(43) Pub. Date: Feb. 6, 2014

(54) Protection Device for Mobile Apparatus with Bluetooth Earphone

(71) Applicant: Ching-Chang Wang, Tainan City (TW)

(72) Inventor: Ching-Chang Wang, Tainan City (TW)

(21) Appl. No.: 13/566,215

(22) Filed: Aug. 3, 2012

(51) Int. Cl. H05K 7/14

(52) U.S. Cl. 361/807

(57) ABSTRACT

A protection device includes a frame unit for protecting a mobile apparatus, a support seat mounted on the frame unit, a bluetooth earphone unit mounted on the support seat, and a mobile power unit mounted on the frame unit. The frame unit includes a main frame for mounting the mobile apparatus, and a mounting board mounted on the main frame for mounting the support seat and the mobile power unit. Thus, the mobile apparatus is received in the main frame of the frame unit, the bluetooth earphone unit is mounted on the support seat, and the mobile power unit and the support seat are mounted on the mounting board of the frame unit, so that the mobile apparatus, the mobile power unit and the bluetooth earphone unit are supported and carried by the frame unit.

### BACKGROUND OF THE INVENTION

1. Field of the Invention

The present invention relates to a protection device and, more particularly, to a protection device for a mobile apparatus.

2. Description of the Related Art

A conventional protection device for a mobile apparatus, such as a cell phone, digital camera, global positioning system (GPS), car video recorder and the like, comprises a back guard board for mounting the mobile apparatus, and two side guard plates mounted on two opposite sides of the back guard board and locked onto two opposite sides of the mobile apparatus respectively. The back guard board has a top provided with an upper locking portion locked onto the top of the mobile apparatus and a bottom provided with a lower locking portion locked onto the bottom of the mobile apparatus. However, the conventional protection device can only be used to protect the mobile apparatus and does not have a charging function so that the user has to additionally prepare a charger or back-up battery to charge or provide an electric power to the mobile apparatus, thereby causing inconvenience to the user. In addition, the conventional protection device cannot receive a bluetooth earphone so that the user has to additionally carry a bluetooth earphone, thereby causing inconvenience to the user.

### BRIEF SUMMARY OF THE INVENTION

In accordance with the present invention, there is provided a protection device for a mobile apparatus, comprising a frame unit for protecting a mobile apparatus, a support seat mounted on the frame unit, a bluetooth earphone unit mounted on the support seat, and a mobile power unit mounted on the frame unit. The frame unit includes a main frame for mounting the mobile apparatus, and a mounting board mounted on the main frame for mounting the support seat and the mobile power unit. The support seat is mounted on the mounting board of the frame unit. The support seat has an interior provided with a receiving chamber for mounting the bluetooth earphone unit. The bluetooth earphone unit is mounted in the receiving chamber of the support seat. The bluetooth earphone unit includes a bluetooth earphone inserted into the receiving chamber of the support seat, and a earplug connected with the bluetooth earphone. The earplug of the bluetooth earphone unit is insertable into a user's ear. The mobile power unit is mounted on the mounting board of the frame unit. The mobile power unit includes a mobile power supply secured on the mounting board of the frame unit, and a charging plug connected with the mobile power supply.

The receiving chamber of the support seat has a sidewall provided with at least two electrically connecting holes. The bluetooth earphone of the bluetooth earphone unit has a side provided with at least two electrically connecting ports which are electrically connected with the electrically connecting holes of the support seat. The electrically connecting ports of the bluetooth earphone are inserted into the electrically connecting holes of the support seat respectively. The mobile power supply of the mobile power unit is juxtaposed to the support seat and is electrically connected with the electrically connecting holes of the support seat. Thus, the mobile power supply of the mobile power unit is electrically connected with the electrically connecting ports of the bluetooth earphone through the electrically connecting holes of the support seat to supply an electric power to the bluetooth earphone of the bluetooth earphone unit.

The earplug of the bluetooth earphone unit is pivotally connected with the bluetooth earphone. The earplug of the bluetooth earphone unit is pivotable relative to the bluetooth earphone to adjust the angle of the earplug relative to the bluetooth earphone.

The mobile power unit further includes a solar panel mounted on and connected with the mobile power supply. Thus, the solar panel of the mobile power unit can convert an optical energy into an electric power and provide the electric power to the mobile power supply.

The mobile apparatus is preferably a cell phone, camera, global positioning system (GPS) or car video recorder.

The primary objective of the present invention is to provide a protection device for a mobile apparatus with a bluetooth earphone.

According to the primary advantage of the present invention, the mobile apparatus is received in the main frame of the frame unit, the bluetooth earphone unit is mounted on the support seat, and the mobile power unit and the support seat are mounted on the mounting board of the frame unit, so that the mobile apparatus, the mobile power unit and the bluetooth earphone unit are supported by the frame unit to facilitate the user carrying and storing the mobile apparatus, the mobile power unit and the bluetooth earphone unit.

According to another advantage of the present invention, the mobile power unit can charge the mobile apparatus instantaneously without having to additionally prepare a charger or back-up battery.

According to a further advantage of the present invention, the mobile power unit can provide an electric power to the bluetooth earphone unit to facilitate the user employing the bluetooth earphone unit.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is an exploded perspective view of a protection device for a mobile apparatus in accordance with the preferred embodiment of the present invention.

FIG. 2 is a perspective assembly view of the protection device for a mobile apparatus as shown in FIG. 1.

FIG. 3 is an exploded perspective view of a protection device for a mobile apparatus in accordance with another preferred embodiment of the present invention.

### DETAILED DESCRIPTION OF THE INVENTION

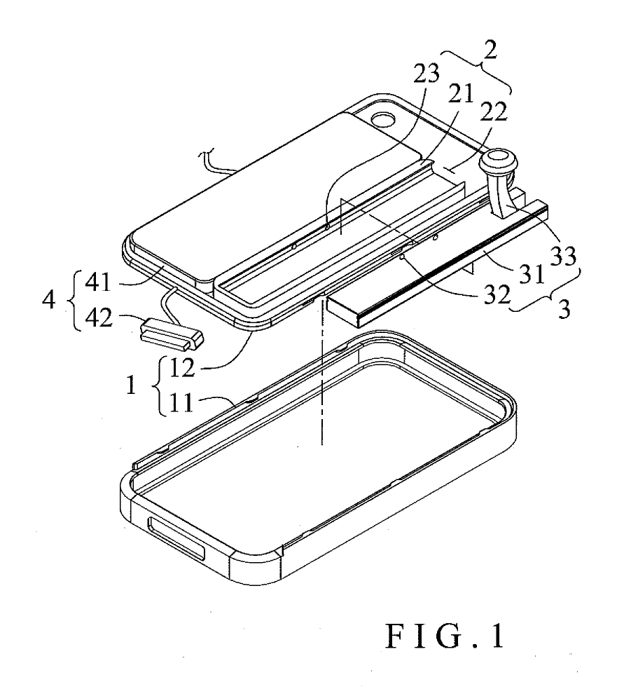

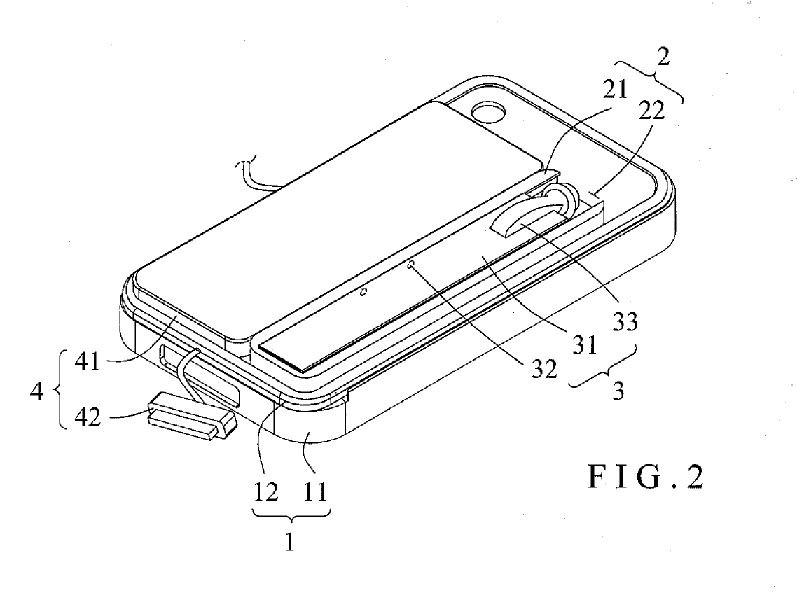

Referring to the drawings and initially to FIGS. 1 and 2, a protection device for a mobile apparatus in accordance with the preferred embodiment of the present invention comprises a frame unit 1 for protecting a mobile apparatus, a support seat 2 mounted on the frame unit 1, a bluetooth earphone unit 3 mounted on the support seat 2, and a mobile power unit 4 mounted on the frame unit 1.

The mobile apparatus is preferably a cell phone, camera, global' positioning system (GPS) or car video recorder.

The frame unit 1 includes a main frame 11 for mounting the mobile apparatus, and a mounting board 12 mounted on the main frame 11 for mounting the support seat 2 and the mobile power unit 4. The mounting board 12 of the frame unit 1 is removably mounted on the main frame 11.

The support seat 2 is mounted on the mounting board 12 of the frame unit 1. Preferably, the support seat 2 is secured on the mounting board 12 of the frame unit 1. The support seat 2 has an elongate shape and has an interior provided with a receiving chamber 22 for mounting the bluetooth earphone unit 3. The receiving chamber 22 of the support seat 2 has a sidewall 21 provided with at least two electrically connecting holes 23.

The bluetooth earphone unit 3 is mounted in the receiving chamber 22 of the support seat 2. The bluetooth earphone unit 3 includes a bluetooth earphone 31 inserted into the receiving chamber 22 of the support seat 2, and a earplug 33 connected with the bluetooth earphone 31. The bluetooth earphone 31 of the bluetooth earphone unit 3 is removably mounted in the receiving chamber 22 of the support seat 2. The bluetooth earphone 31 of the bluetooth earphone unit 3 has a side provided with at least two electrically connecting ports 32 which are electrically connected with the electrically connecting holes 23 of the support seat 2. The electrically connecting ports 32 of the bluetooth earphone 31 are inserted into the electrically connecting holes 23 of the support seat 2 respectively. The earplug 33 of the bluetooth earphone unit 3 is pivotally connected with the bluetooth earphone 31 and is insertable into a user's ear. The earplug 33 of the bluetooth earphone unit 3 is pivotable relative to the bluetooth earphone 31 to adjust the angle of the earplug 33 relative to the bluetooth earphone 31.

The mobile power unit 4 is mounted on the mounting board 12 of the frame unit 1. The mobile power unit 4 includes a mobile power supply 41 secured on the mounting board 12 of the frame unit 1, and a charging plug 42 connected with the mobile power supply 41. The charging plug 42 of the mobile power unit 4 is insertable into a charging slot of the mobile apparatus so that the mobile power supply 41 of the mobile power unit 4 is electrically connected with the mobile apparatus to charge the mobile apparatus. The mobile power supply 41 of the mobile power unit 4 is a flat power supply matching the mobile apparatus. The mobile power supply 41 of the mobile power unit 4 is juxtaposed to the support seat 2 and is electrically connected with the electrically connecting holes 23 of the support seat 2. Thus, the mobile power supply 41 of the mobile power unit 4 is electrically connected with the electrically connecting ports 32 of the bluetooth earphone 31 through the electrically connecting holes 23 of the support seat 2 to supply an electric power to the bluetooth earphone 31 of the bluetooth earphone unit 3.

In assembly, the mobile apparatus is received in the main frame 11 of the frame unit 1. Then, the mounting board 12 of the frame unit 1 is mounted on the main frame 11. Then, the charging plug 42 of the mobile power unit 4 is inserted into the charging slot of the mobile apparatus so that the mobile power supply 41 of the mobile power unit 4 is electrically connected with the mobile apparatus to charge the mobile apparatus. Then, the bluetooth earphone 31 of the bluetooth earphone unit 3 is inserted into the receiving chamber 22 of the support seat 2. At this time, the electrically connecting ports 32 of the bluetooth earphone 31 are inserted into the electrically connecting holes 23 of the support seat 2 respectively so that the bluetooth earphone 31 of the bluetooth earphone unit 3 is received in the receiving chamber 22 of the support seat 2 more solidly and stably. In such a manner, the mobile power supply 41 of the mobile power unit 4 is electrically connected with the electrically connecting ports 32 of the bluetooth earphone 31 through the electrically connecting holes 23 of the support seat 2 to supply an electric power to the bluetooth earphone 31 of the bluetooth earphone unit 3. Thus, the frame unit 1 can protect the mobile apparatus, and the mobile power unit 4 can charge the mobile apparatus and provide an electric power to the bluetooth earphone unit 3.

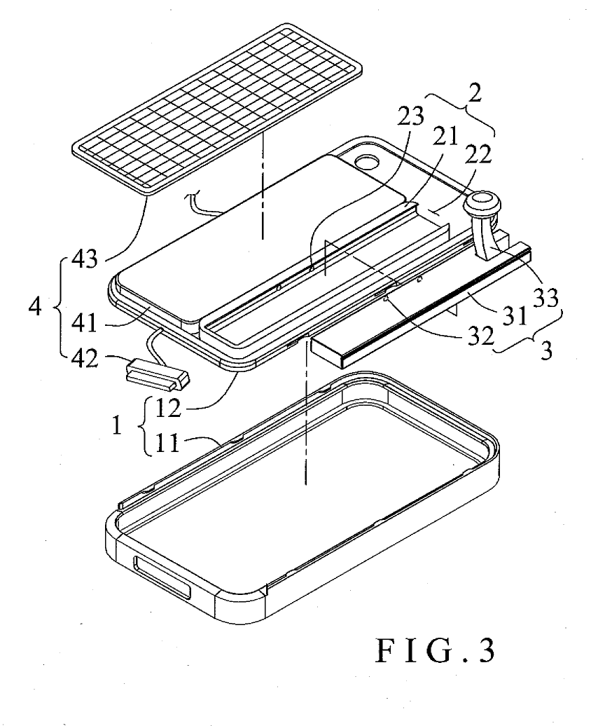

Referring to FIG. 3, the mobile power unit 4 further includes a solar panel 43 mounted on and connected with the mobile power supply 41. Thus, the solar panel 43 of the mobile power unit 4 can convert an optical energy into an electric power and provide the electric power to the mobile power supply 41.

Accordingly, the mobile apparatus is received in the main frame 11 of the frame unit 1, the bluetooth earphone unit 3 is mounted on the support seat 2, and the mobile power unit 4 and the support seat 2 are mounted on the mounting board 12 of the frame unit 1, so that the mobile apparatus, the mobile power unit 4 and the bluetooth earphone unit 3 are supported by the frame unit 1 to facilitate the user carrying and storing the mobile apparatus, the mobile power unit 4 and the bluetooth earphone unit 3. In addition, the mobile power unit 4 can charge the mobile apparatus instantaneously without having to additionally prepare a charger or back-up battery. Further, the mobile power unit 4 can provide an electric power to the bluetooth earphone unit 3 to facilitate the user employing the bluetooth earphone unit 3.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A protection device for a mobile apparatus, comprising:
a frame unit for protecting a mobile apparatus;
a support seat mounted on the frame unit;
a bluetooth earphone unit mounted on the support seat; and
a mobile power unit mounted on the frame unit;
wherein the frame unit includes a main frame for mounting the mobile apparatus, and a mounting board mounted on the main frame for mounting the support seat and the mobile power unit;
the support seat is mounted on the mounting board of the frame unit;
the support seat has an interior provided with a receiving chamber for mounting the bluetooth earphone unit;
the bluetooth earphone unit is mounted in the receiving chamber of the support seat;
the bluetooth earphone unit includes a bluetooth earphone inserted into the receiving chamber of the support seat, and a earplug connected with the bluetooth earphone;
the earplug of the bluetooth earphone unit is insertable into a user's ear;
the mobile power unit is mounted on the mounting board of the frame unit;
the mobile power unit includes a mobile power supply secured on the mounting board of the frame unit, and a charging plug connected with the mobile power supply.

2. The protection device for a mobile apparatus of claim 1, wherein
the receiving chamber of the support seat has a sidewall provided with at least two electrically connecting holes;
the bluetooth earphone of the bluetooth earphone unit has a side provided with at least two electrically connecting ports which are electrically connected with the electrically connecting holes of the support seat;
the electrically connecting ports of the bluetooth earphone are inserted into the electrically connecting holes of the support seat respectively;
the mobile power supply of the mobile power unit is juxtaposed to the support seat and is electrically connected with the electrically connecting holes of the support seat; and
the mobile power supply of the mobile power unit is electrically connected with the electrically connecting ports of the bluetooth earphone through the electrically connecting holes of the support seat to supply an electric power to the bluetooth earphone of the bluetooth earphone unit.

3. The protection device for a mobile apparatus of claim 1, wherein
the earplug of the bluetooth earphone unit is pivotally connected with the bluetooth earphone; and
the earplug of the bluetooth earphone unit is pivotable relative to the bluetooth earphone to adjust the angle of the earplug relative to the bluetooth earphone.

4. The protection device for a mobile apparatus of claim 1, wherein
the mobile power unit further includes a solar panel mounted on and connected with the mobile power supply; and
the solar panel of the mobile power unit converts an optical energy into an electric power and provides the electric power to the mobile power supply.

5. The protection device for a mobile apparatus of claim 1, wherein the mobile apparatus is a cell phone, camera, global positioning system (GPS) or car video recorder.
